(19) United States
(12) Patent Application Publication
(10) Pub. No.: US 2022/0147274 A1
(43) Pub. Date: May 12, 2022

(54) STORAGE DEVICE AND OPERATING METHOD THEREOF

(71) Applicant: SK hynix Inc., Icheon-si (KR)

(72) Inventors: Jae Hoon KIM, Icheon-si (KR); Eui Cheol LIM, Icheon-si (KR)

(21) Appl. No.: 17/319,840

(22) Filed: May 13, 2021

(30) Foreign Application Priority Data
Nov. 9, 2020 (KR) 10-2020-0148502

(51) Int. Cl. G06F 3/06; G11C 11/406; G11C 11/4076

(52) U.S. Cl. CPC G06F 3/0659; G06F 3/0619; G06F 3/0644; G11C 11/4091; G06F 3/0673; G11C 11/406; G11C 11/4076; G06F 3/0653

(57) ABSTRACT

A storage device includes: a memory device including memory cells for storing data, the memory cells grouped into a plurality of memory banks; and a memory controller coupled in communication with the memory device and configured to provide commands to the memory device and access one or more memory banks based on address information associated with the commands. The memory controller may count a number of access times that the memory controller has accessed to first memory bank by increasing the number of access times to the first memory bank based on a time interval between first active command and second active command for the first memory bank, and transmit, to the memory device, a control signal to perform a refresh operation on the first memory bank when the number of access times counted exceeds a predetermined number.

### CROSS-REFERENCE TO RELATED APPLICATION

This patent document claims priority to and benefits of the Korean patent application number 10-2020-0148502, filed on Nov. 9, 2020, which is incorporated herein by reference in its entirety.

### TECHNICAL FIELD

The technology and implementations disclosed in this patent document generally relates to an electronic device, and more particularly, to a storage device and an operating method thereof.

### BACKGROUND

Storage devices refer to electronic components that are configured to store data on a permanent or temporary basis. Each storage device may include one or more storage medium to store data and operate based on a request from a host device such as a computer or a smart phone. The storage device may include a storage medium for storing data and may further include a memory controller for controlling the storage medium to store or retrieve data. The storage device can be classified based on the type of storage medium. For example, the memory device used as a storage medium is classified into a volatile memory device and a nonvolatile memory device.

A volatile memory device may store data only when power is supplied. Thus, such a volatile memory device loses its data in the absence of power. Examples of the volatile memory device include a Static Random Access Memory (SRAM) or a Dynamic Random Access Memory (DRAM).

A nonvolatile memory device can retain its data in the absence of power. The nonvolatile memory device may include a Read Only Memory (ROM), a Programmable ROM (PROM), an Electrically Programmable ROM (EPROM), an Electrically Erasable ROM (EEROM), or a flash memory.

### SUMMARY

Embodiments provide a storage device for performing an improved refresh operation and an operating method of the storage device.

In one aspect of the disclosed technology, a storage device is provided to include: a memory device including memory cells for storing data, the memory cells grouped into a plurality of memory banks; and a memory controller coupled in communication with the memory device and configured to provide commands to the memory device and access one or more memory banks based on address information associated with the commands, wherein the memory controller is further configured to: count a number of access times that the memory controller has accessed to first memory bank by increasing the number of access times to the first memory bank based on a time interval between first active command and second active command for the first memory bank; and transmit, to the memory device, a control signal to perform a refresh operation on the first memory bank when the number of access times counted exceeds a predetermined number.

In another aspect of the disclosed technology, a storage device is provided to include a memory device including a plurality of memory banks; and a memory controller configured to access any one memory bank among the plurality of memory banks, based on a physical address corresponding to an active command, wherein the memory controller: counts a number of times of access to each of the plurality of memory banks, and determines an increment of the number of times of access according to a time interval between a first active command and a second active command for each of the plurality of memory banks; and controls the memory device to perform a refresh operation on a target bank to which the number of times of access exceeds a predetermined number of times among the plurality of memory banks, when the target bank occurs.

In another aspect of the disclosed technology, a storage device is provided to include: a memory device; and a memory controller configured to: count a number of times of access to each of a plurality of memory banks of the memory device, based on a physical address corresponding to an active command for accessing any one memory bank among the plurality of memory banks; determine a correction value of the number of times of access according to an input period of an active command for each of the plurality of memory banks; and control the memory device to perform a refresh operation on the one memory bank among the plurality of memory banks, when the number of times of access to the one memory bank exceeds a predetermined threshold number of times.

In another aspect of the disclosed technology, a storage device is provided to include: a memory device including a plurality of memory banks; and a memory controller in communication with the memory device and configured to transmit, to the memory device, a first command and a second command subsequent to the first command that are associated with a memory bank; identify the memory bank to which the memory controller accesses based on the first command and the second command; count a number of access times that the memory controller has accessed to the memory bank based on a time interval between the first command and the second command; and transmit a control signal, to the memory device, to perform a refresh operation on the memory block in case that the number of access times to the memory bank exceeds a predetermined threshold number.

In another aspect of the disclosed technology, a method for operating a storage device including a plurality of memory banks is provided. The method includes: generating a first command and a second command for controlling a memory device including memory banks to perform corresponding operations on a memory bank, each memory bank including memory cells for storing data; counting a number of access times to the memory bank based on a time interval between of the first command and the second command; transmitting a control signal to perform a refresh operation on the memory bank in case that the number of access times to the memory bank exceeds a threshold number.

In another aspect of the disclosed technology, a method for operating a storage device including a plurality of memory banks is provided. The method includes: generating an active command in response to a request received from a host; accumulating a number of times of access to a target bank among the plurality of memory banks, based on a physical address corresponding to the active command; determining a correction value of the number of times of access according to an input period of an active command for the target bank; determining whether the number of times of access to the target bank exceeds a predetermined threshold number of times; and performing a refresh operation on the target bank, when the number of times of access exceeds the threshold number of times.

### BRIEF DESCRIPTION OF THE DRAWINGS

Example embodiments will now be described with reference to the accompanying drawings.

FIG. 1 is a block diagram illustrating a storage device in accordance with an embodiment of the disclosed technology.

FIG. 2 is a diagram illustrating a memory device in accordance with an embodiment of the disclosed technology.

FIG. 3 is a circuit diagram illustrating an interference phenomenon between memory cells of a DRAM in accordance with an embodiment of the disclosed technology.

FIG. 4 is a diagram illustrating a number of times of access to a memory bank and a refresh operation in accordance with an embodiment of the disclosed technology.

FIG. 5 is a diagram illustrating a conventional refresh operation.

FIG. 6 is a diagram illustrating a refresh operation in accordance with an embodiment of the disclosed technology.

FIG. 7 is a diagram illustrating an idle state in accordance with an embodiment of the disclosed technology.

FIG. 8 is a diagram illustrating a page hit in accordance with an embodiment of the disclosed technology.

FIG. 9 is a diagram illustrating a configuration of a memory controller in accordance with an embodiment of the disclosed technology.

FIG. 10 is a diagram illustrating an operating method of the storage device in accordance with an embodiment of the disclosed technology.

FIG. 11 is a block diagram illustrating a memory controller in accordance with another embodiment of the disclosed technology.

FIG. 12 is a diagram illustrating a memory card system in accordance with an embodiment of the disclosed technology.

FIG. 13 is a diagram illustrating a Solid State Drive (SSD) in accordance with an embodiment of the disclosed technology.

FIG. 14 is a diagram illustrating a user system in accordance with an embodiment of the disclosed technology.

### DETAILED DESCRIPTION

The specific structural or functional features disclosed herein are merely illustrative examples for implementing disclosed technology and implementations of the disclosed technology are not limited to those specific examples.

In describing the embodiments, description of technologies that are known in the art and are not directly related to the present disclosure is omitted.

Hereinafter, exemplary embodiments of the disclosed technology will be described in detail with reference to the accompanying drawings.

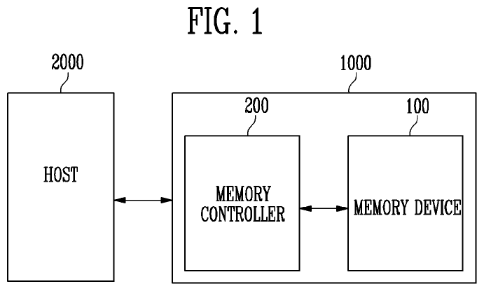

FIG. 1 is a block diagram illustrating a storage device in accordance with an embodiment of the disclosed technology.

Referring to FIG. 1, the storage device 1000 may include a memory device 100 and a memory controller 200.

The storage device 1000 may be manufactured as any one of various types of storage devices according to a host interface that is a communication interface between the host 2000 and the storage device 1000. For example, the storage device 1000 may be implemented with any one of a variety of types of storage devices, such as a Solid State Drive (SSD), a Multi-Media Card (MMC), an Embedded MMC (eMMC), a Reduced Size MMC (RS-MMC), a micro-MMC (micro-MMC), a Secure Digital (SD) card, a mini-SD card, a micro-SD card, a Universal Serial Bus (USB) storage device, a Universal Flash Storage (UFS) device, a Compact Flash (CF) card, a Smart Media Card (SMC), a memory stick, or others.

The storage device 1000 may be implemented as any one of various kinds of package types. For example, the storage device 1000 may be implemented as any one of various kinds of package types such as a Package-On-Package (POP), a System-In-Package (SIP), a System-On-Chip (SOC), a Multi-Chip Package (MCP), a Chip-On-Board (COB), a Wafer-level Fabricated Package (WFP), or a Wafer-level Stack Package (WSP).

The memory device 100provide a storage space where data to be processed and/or instructions to be executed is stored. The memory device 100 may include the logic needed to read from and write to the memory device 100 and be operated in response to requests from the memory controller 200. Also, the memory device 100 may include a plurality of memory dies, and each of the plurality of memory dies may include a memory cell array including a plurality of memory cells for storing data.

The memory cell array may include a plurality of memory banks. Each memory bank may include a plurality of pages, and each page corresponds to a plurality of memory cells. In an embodiment of the disclosed technology, read and program (write) operations are performed on a page basis, and erase operations are performed on a block basis.

The memory device 100 may be implemented as a Double Data Rate Synchronous Dynamic Random Access Memory (DDR SDRAM), a Low Power Double Data Rate 4 (LPDDR4) SDRAM, a Graphics Double Data Rate (GDDR) SRAM, a Low Power DDR (LPDDR), a Rambus Dynamic Random Access Memory (RDRAM), a NAND flash memory, a vertical NAND flash memory, a NOR flash memory, a Resistive Random Access Memory (RRAM), a Phase-Change Random Access Memory (PRAM), a Magnetoresistive Random Access Memory (MRAM), a Ferroelectric Random Access Memory (FRAM), a Spin Transfer Torque Random Access Memory (STT-RAM), or others. In this patent document, some implementations may be explained assuming that the memory device 100 is implemented as a NAND flash memory but other implementations are also possible.

The memory controller 200 can access the memory device 100 based on requests form the user/host by providing command/address signals to the memory controller 200. In some implementations, the memory device 100 may receive, from the memory controller 200, a command and an address in which the command is performed or executed. The memory device 100 may access an area selected by the received address in the memory cell array. Upon accessing the selected area, the memory device 100 performs an operation corresponding to the received command on the selected area. For example, the memory device 100 may perform a write operation (program operation), a read operation, and/or an erase operation. In the program operation, data is written to the area selected by the address. In the read operation, data is read from the area selected by the address. In the erase operation, data is erased from the area selected by the address.

The memory controller 200 may control overall operations of the storage device 1000.

When power is applied to the storage device 1000, the memory controller 200 may execute firmware (FW). The memory controller 200 may control overall operations of the storage device 1000 by using the firmware.

In some implementations, the memory controller 200 may receive data and a Logical Address (LA) from the host 2000, and translate the LA into a Physical Address (PA) representing an address of memory cells to or from which data is to be written or read. The LA may be a Logical Block Address (LBA), and the PA may be a Physical Block Address (PBA).

The memory controller 200 may control the memory device 100 to perform a program operation, a read operation, and/or an erase operation, or others, based on a request from the host 2000. In the program operation, the memory controller 200 may provide a program command, a PBA, and data to the memory device 100. In the read operation, the memory controller 200 may provide a read command and a PBA to the memory device 100. In the erase operation, the memory controller 200 may provide an erase command and a PBA to the memory device 100.

In some implementations, the memory controller 200 may provide interfacing between the host 2000 and the memory device 100. The memory controller 200 may exchange data and signals with the memory device 100 through control signal lines, an address line, data lines, or others. In some implementations, the memory controller 100 may transfer, to the memory device 100, a refresh command (Refresh CMD) for instructing the memory device 100 to perform a refresh operation.

The memory controller 200 may transfer a command set to the memory device 100 based on control signals. In a general DRAM, an active command and an auto refresh command may be determined by a combination of the control signals. In addition, a self-refresh command may be identified by a combination of the auto refresh command and a clock enable signal.

When interference (or disturb) is concentrated on a specific memory area, some implementations of the disclosed technology provide a storage device 1000 including the memory device 100 and the memory controller 200 that is configured to perform a refresh operation on the specific memory area on which the interference is concentrated. In some implementations, to this end, the memory controller 200 may count a number of times that has accessed to a memory bank. When the number of access times to a specific memory bank reaches a threshold number of times, the memory controller 200 may perform a refresh operation on the specific memory bank.

The host 2000 may communicate with the storage device 1000, using at least one of various communication manners, such as a Universal Serial bus (USB), a Serial AT Attachment (SATA), a High Speed Inter Chip (HSIC), a Small Computer System Interface (SCSI), Firewire, a Peripheral Component Interconnection (PCI), a PCI express (PCIe), a Non-Volatile Memory express (NVMe), a universal flash storage (UFS), a Secure Digital (SD), a Multi-Media Card (MMC), an embedded MMC (eMMC), a Dual In-line Memory Module (DIMM), a Registered DIMM (RDIMM), or a Load Reduced DIMM (LRDIMM).

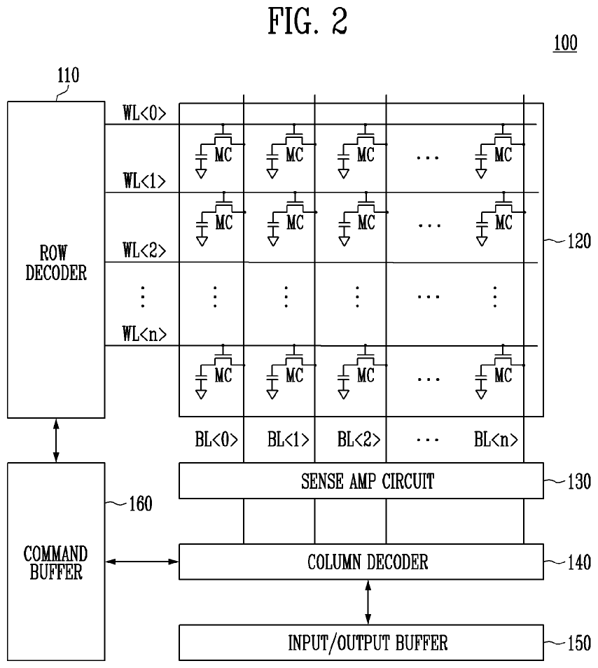

FIG. 2 is a diagram illustrating a memory device in accordance with an embodiment of the disclosed technology.

Referring to FIG. 2, the memory device 100 may include a row decoder 110, a memory cell array 120, a sense amp circuit 130, a column decoder 140, an input/output buffer 150, and a command buffer 160.

The row decoder 110 may select a word line of the memory cell array 120 by decoding a row address. Specifically, the row decoder 110 may select a word line of a memory cell to be accessed in response to an input address ADD. The row decoder 110 may enable the corresponding word line by decoding the input address ADD.

In the memory cell array 120, a plurality of memory cells MC may be respectively connected to word lines WL and bit lines BL to be arranged in a row direction and a column direction. The memory cell array 120 may include a plurality of memory cells in a matrix form of rows and columns. Each memory cell of the memory cell array 120 may be configured with a cell capacitor and an access transistor. A gate of the access transistor AT may be connected to any corresponding word line WL<i>. Specifically, the gate of the access transistor AT may be connected to any one word line WL<i> among the word lines WL arranged in the row direction. A drain of the access transistor AT may be connected to any corresponding bit line BL<i>. Specifically, one end of the access transistor AT may be connected to a bit line BL or a complementary bit line BLB, which is arranged in the column direction. Also, the other end of the access transistor AT may be connected a cell capacitor CC. In addition, a plurality of memory cells connected to the same word line may constitute one page unit.

The sense amp circuit 130 may sense and amplify data of a memory cell through a bit line. The sense amp circuit 130 may write data in a selected memory cell or sense data which has already been written through a selected bit line. The sense amp circuit 130 may sense and output data stored in a memory cell through a bit line. Also, the sense amp circuit 130 may further include components for storing input data in a selected memory cell. The sense amp circuit 130 may rewrite data stored in a memory cell in a refresh operation. The sense amp circuit 130 may perform a refresh operation on selected memory cells under the control of the command buffer 160. That is, the sense amp circuit 130 may amplify and rewrite data of the selected memory cells to perform the refresh operation.

The column decoder 140 may select a bit line of the memory cell array 120 by decoding a column address. Specifically, the column decoder 140 may select a bit line of a memory cell to be accessed in response to an input address ADD. That is, the column decoder 140 may select a bit line of a memory cell to or from which data is to be input or output.

The input/output buffer 150 may buffer write data applied from the outside and allow the buffered write data to be stored in a selected memory cell. The input/output buffer 150 may buffer data read from a memory cell and output the buffered data to the outside.

The command buffer 160 may buffer a command CMD applied from the outside. The memory device 100 may decode a command received from the memory controller, and perform an operation of the memory device 100 based on the received command. In some implementations, the command buffer 160 may control the memory device 100 to operate based on a command CMD received from the memory controller 200, in response to the command CMD. For example, the command buffer 160 may decode the command CMD input through a combination of control signals. Also, the command buffer 160 may determine the command CMD input from the memory controller 200 based on signals of the input command CMD.

For example, in a general DRAM, an active command may be determined by a combination of control signals. The command buffer 160 may determine a refresh operation command Refresh_CMD by decoding an active command Active CMD. Also, the command buffer 160 may provide the refresh operation command Refresh_CMD to the row decoder 110 and the column decoder 140. Then, the command buffer 160 may control the row decoder 110 and the sense amp circuit 130 by using the refresh operation command Refresh_CMD.

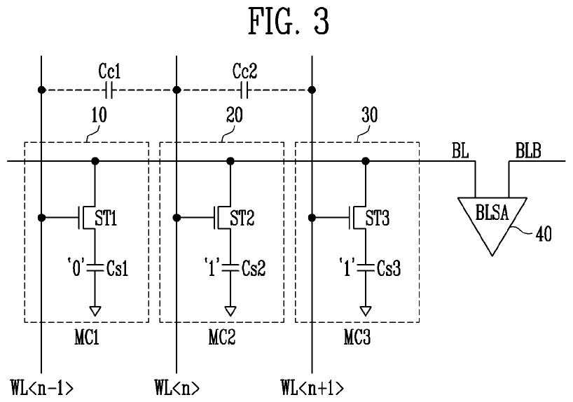

In some implementations, a state of cell data stored in a memory cell may be determined based on a quantity of charges stored in a storage capacitor SC of the memory cell. The charges stored in the storage capacitor SC may be leaked as time elapses. In addition, with the development of technologies, the memory device 100 becomes high in capacity and high in integration, and a distance between word lines (e.g., WL<1> and WL<2>) is gradually decreased. Data stored in memory cells frequently connected to a specific word line (e.g., WL<1>) may be corrupted. Data stored in memory cells connected to adjacent word lines (e.g., WL<0> and WL<2>) that are adjacent to the specific word line (e.g., WL<1>) may be corrupted due to spatial disturbance which results from coupling influence, etc. Therefore, a refresh operation of restoring cell data before the change of a state of the cell data may be required so as to ensure the reliability of data in a volatile memory device. Hereinafter, an interference phenomenon between memory cells of a DRAM will be described with reference to FIG. 3.

FIG. 3 is a circuit diagram illustrating an interference phenomenon between memory cells of a DRAM in accordance with an embodiment of the disclosed technology.

Referring to FIG. 3, a first memory cell 10, a second memory cell 20, and a third memory cell 30, and a bit line sensing amplifier 40 are illustrated. In FIG. 3, it is assumed that each of the plurality of memory cells 10, 20, and 30 is connected to the same bit line BL. In addition, the first memory cell 10 may be connected to an (n−1)th word line WL<n−1>, the second memory cell 20 may be connected to an nth word line WL<n>, and the third memory cell 30 may be connected to an (n+1)th word line WL<n+1>. The first memory cell 10 may include a first access transistor ST1 and a first cell capacitor CS1. A gate terminal of the first access transistor ST1 may be connected to the (n−1)th word line WL<n−1>, and one end of the first access transistor ST1 may be connected to the bit line BL. The second memory cell 20 may include a second access transistor ST2 and a second cell capacitor Cs2. A gate terminal of the second access transistor ST2 may be connected to the nth word line WL<n>, and one end of the second access transistor ST2 may be connected to the bit line BL. In addition, the third memory cell 30 may include a third access transistor ST3 and a third cell capacitor Cs3. A gate terminal of the third access transistor ST3 may be connected to the (n+1)th word line WL<n+1>, and one end of the third access transistor ST3 may be connected to the bit line BL.

The bit line sensing amplifier 40 may include an N-sensing amplifier NSA for discharging a low-potential bit line among bit lines BL and BLB and a P-sensing amplifier PSA for charging a high-potential bit line among the bit lines BL and BLB. In a refresh operation, the bit line sensing amplifier 40 may rewrite stored data to a selected memory cell through the N-sensing amplifier NSA or the P-sensing amplifier PSA.

In a read operation or a write operation, a select voltage (e.g., Vpp) may be provided to the nth word line WL<n>. Then, voltages of adjacent word lines (e.g., WL<n−1> and WL<n+1>) may increase due to a capacitive coupling effect even when the select voltage is not provided. Such capacitive coupling is illustrated as parasitic capacities Cc1 and Cc2 between the word lines. When the word line WL<n> is repeatedly accessed during a period in which the refresh operation is not performed, charges stored in the cell capacitors Cs1 and Cs3 of the memory cells 10 and 30 connected to the word lines WL<n−1> and WL<n+1> may be gradually leaked. In this case, the reliability of logic ‘0’ stored in the first cell capacitor Cs1 and logic ‘1’ stored in the third cell capacitor Cs3 may be difficult to be ensured. Accordingly, it is required to refresh the memory cells connected to the word lines WL<n−1> and WL<n+1> at an appropriate time.

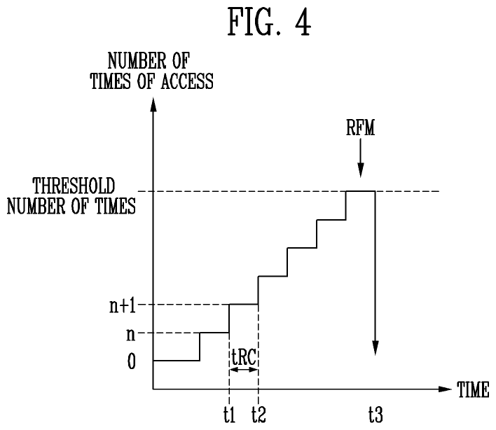

FIG. 4 is a diagram illustrating a number of times of access to a memory bank and a refresh operation in accordance with an embodiment of the disclosed technology.

Referring to FIG. 4, a graph showing that a number of access times to a specific memory block is initialized when the number of access times reaches a threshold number. The graph shown in FIG. 4 shows a relationship between a number of access times to a memory bank and time.

In accordance with an embodiment of the disclosed technology, the memory device 100 may include a plurality of memory banks. In addition, the memory controller 200 may count a number of access times to each of the plurality of memory banks, and store the counted number of times of access. For example, at the time t1, the storage device 1000 may receive an internal operation request for a specific memory bank from the host 2000. In response to the internal operation request for the specific memory bank received at the time t1, the specific memory bank is accessed one more time. Thus, after t1, the storage device 1000 may increase the number of access times to the specific memory bank by one (1). For example, the storage device 1000 may update the number of access times to the specific memory bank from n to (n+1).

When the number of access times to the specific memory bank exceeds the threshold number, the memory controller 200 may control the memory controller 100 to perform a refresh operation on the corresponding specific memory bank so as to ensure the reliability of data stored in the specific memory bank. For example, at the time t3 which is after the number of access times to the specific memory bank exceeds the threshold number, the memory controller 200 may control the memory device 100 to perform the refresh operation and initialize the number of access times to the specific memory bank.

In the refresh operation, information stored in a memory cell may be rewritten to the memory cell. The refresh operation may be performed by activating a word line at least once within a retention time of the memory cell and sensing and amplifying data. The retention time may refer to a period for which data is maintained in a memory cell without the refresh operation after the data is written in the memory cell. In some implementations, the refresh operation may be performed at constant time intervals without any command from the memory controller 200 or the host 2000. In this patent document, such auto-refresh operation performed without any command from the memory controller 200 or the host 2000 is not separately discussed or convenience of description.

In FIG. 4, tRC may be a period (or time interval) between two accesses to the specific memory bank. Thus, tRC may be a time interval between an nth access to the specific memory bank and an (n+1)th access to the specific memory bank.

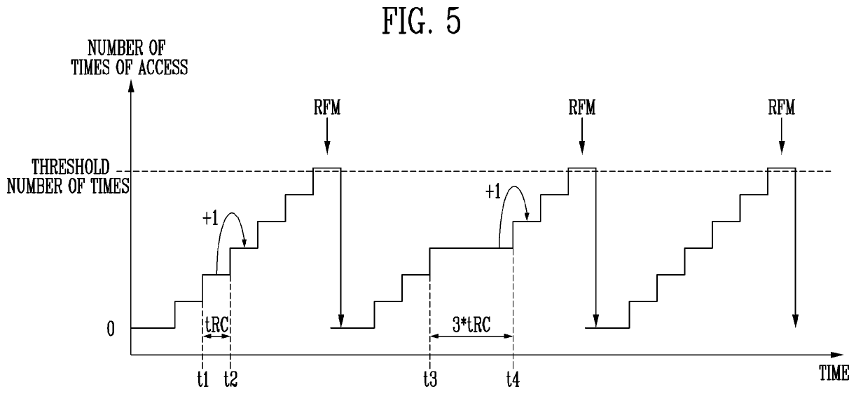

FIG. 5 is a diagram illustrating a conventional refresh operation.

Referring to FIG. 5, during a cycle, the specific memory bank is accessed the number of access times and then a refresh operation on the specific memory bank is performed. The refresh operation allows to initialize the number of access times to the specific memory bank. Such cycle may be repeated.

In the conventional refresh operation, a number of access times is counted for each memory bank and the refresh operation is performed when the number of times of access reached a threshold number. By performing the refresh operation, the number of access times to the specific memory bank is initialized. In the conventional refresh operation, the interference phenomenon cannot minimized when the interval of access to the specific memory bank increases.

In FIG. 5, there are two cases, i.e., the first case (hereinafter, referred to as Case 1) where the specific memory bank is accessed at the time t1, and then accessed again at the time t2 and the second case (hereinafter, referred to as Case 2) where the specific memory bank is accessed at the time t3, and then accessed again at the time t4. In the conventional art, Case 1 and Case 2 may be identical in terms of increasing the number of access times to the specific memory bank by one (1). Specifically, although a time interval between two accesses to the specific memory bank in Case 1 is tRC (sec) and a time interval between two accesses to the specific memory bank in Case 2 is 3*tRC (sec), there is no difference between Case 1 and Case 2 in terms of an increment of the number of access time to the specific memory bank. Therefore, there has been limitations to minimize the interference phenomenon or a charge leakage phenomenon due to an increase in active interval or time interval of accesses to the specific memory bank.

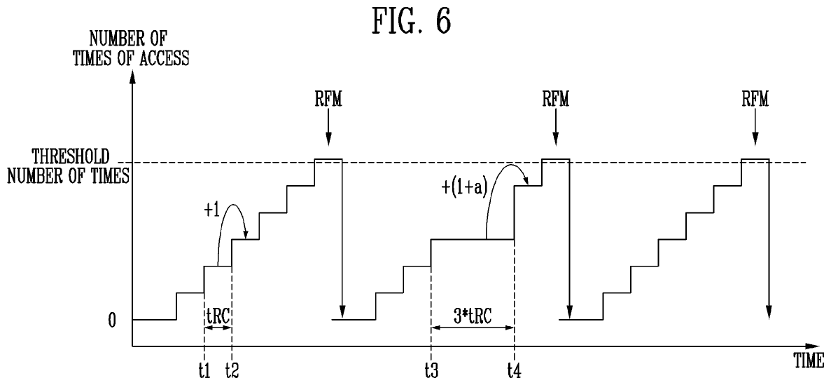

FIG. 6 is a diagram illustrating a refresh operation in accordance with an embodiment of the disclosed technology.

Referring to FIG. 6, during a cycle the specific memory bank is accessed the number of access times and then a refresh operation on the specific memory bank is performed. The refresh operation allows to initialize the number of access times to the specific memory bank. Such cycle may be repeated.

In accordance with the embodiment of the disclosed technology, an interference phenomenon or a charge leakage phenomenon due to an increase in active interval or time interval of access to the specific memory bank can be minimized.

In FIG. 6, there are two cases, i.e., the first case (hereinafter, referred to as Case 1) where the specific memory bank is accessed at the time t1, and then accessed again at the time t2 and the second case (hereinafter, referred to as Case 2) where the specific memory bank is accessed at the time t3, and then accessed again at the time t4. In Case 1, a time interval of access to the specific memory bank is tRC (sec) corresponding to a reference time of access. In Case 2, a time interval of access to the specific memory bank is 3*tRC (sec) greater than the reference time of access. The reference time of access may be defined as a predetermined number of reference clocks.

In accordance with an embodiment of the disclosed technology, the storage device may update or correct a number of access times to the specific memory bank based on a time interval between a previous active command and a current active command for the specific memory bank. The active command may be a command for performing an internal operation by accessing any one of memory banks. The storage device 1000 may determine an increment (+a in FIG. 6), i.e., the amount or degree by which the number of access times to the specific memory is increased, based on the time interval between the active commands, and adjust a period of the refresh operation based on the increment (+a) of the number of access times.

In some implementations, the storage device 1000 may determine the increment (+a) of the number of access times such that the increment (+a) of the number of access times increases as the time interval between the active commands increases. In accordance with an embodiment of the disclosed technology, when the time interval between the active commands is n times of the reference time of access, the increment (+a) of the number of access times may be determined as (n−1). For example, in Case 2 where the time interval of access is 3*tRC (sec), the increment (+a) of the number of access times may be determined as two times. The reference time of access may be defined as a predetermined number of reference clocks.

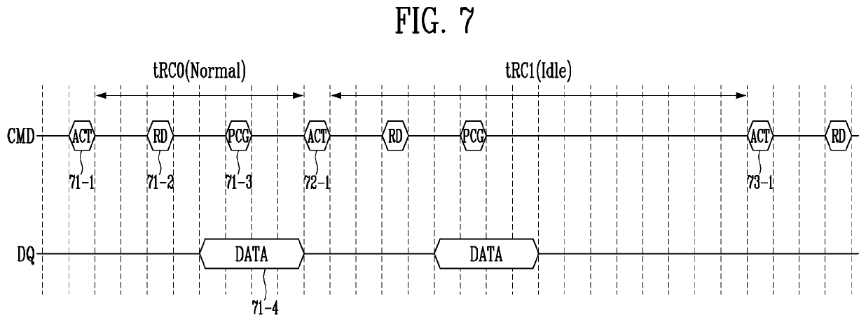

FIG. 7 is a diagram illustrating read operations reading data from a specific memory bank when a memory device is in a busy state (non-idle state) and an idle state in accordance with an embodiment of the disclosed technology.

To perform the read operation on the specific memory device, the memory controller provides the actives commands 71-1 and 72-1 to activate a corresponding word line to a specific memory bank. The storage device 1000 may identify access to the specific memory bank based on the active commands 71-1 and 72-1. The storage device 1000 may calculate a time interval of access to the specific memory bank through a time interval between active commands.

After providing the active commands 71-1, the memory controller 200 may control the memory device 100 to perform a read operation on the specific memory bank by providing a read command 71-2, and a precharge command 71-3. The memory device 100 may read data 71-4 stored in the specific memory bank based on the control of the memory controller 200. In the example of FIG. 7, the memory controller 200 may transmit a second active command 72-2 to the memory device 100 to perform an additional read operation on the specific memory bank. A time interval between the first active command 71-1 and the second active command 72-1 may be a reference time tRC0 of access. The reference time tRC0 of access may be a time interval between active commands when any special event does not occur in the memory device 100 and the memory controller 200. Therefore, the reference time tRC0 of access may be a time interval of a minimum unit.

In some implementations, after the read operation associated with the first active command 71-1 is performed on the specific memory bank, the specific memory bank may be in an idle state in which the specific memory bank stands by without performing an operation due to a reason such as an operation schedule of another memory bank or sharing of an input/output circuit. After the precharge command is transmitted, the specific memory bank may be in the idle state until a next active command is transmitted. A time interval of access to the specific memory bank in the idle state may become longer than a reference time interval of access. For example, the time interval of access in the idle state may be tRC1 as a time interval from the second active command 72-1 to a third active command 73-1, and the reference time interval of access may be tRC0 as a time interval from the first active command 71-1 to the second active command 72-1. Thus, tRC1 may be greater than tRC0.

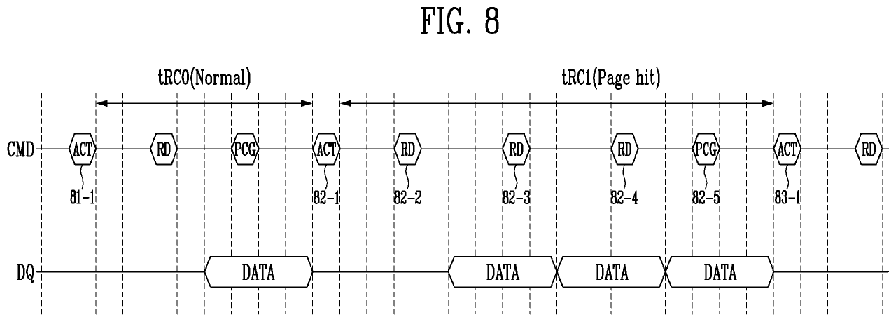

FIG. 8 is a diagram illustrating a page hit in accordance with an embodiment of the disclosed technology.

Referring to FIG. 8, a case where a time interval between active commands increases according to a page hit in accordance with an embodiment of the disclosed technology will be illustrated.

The memory controller 200 may control the memory device 100 to perform a plurality of operations on a specific memory bank after the memory controller 200 transmits a first active command and before the memory controller 200 transmits a second, subsequent active command. Specifically, when the memory controller 200 reads several pages in the specific memory bank, a time interval between active commands may increase. For example, the memory controller 200 may sequentially transmit a second active command 82-1, a plurality of read commands 82-2, 82-3, and 82-4, and a precharge command 82-5 to the memory device 100. Since the memory controller 200 identifies access to the specific memory bank based on an active command, the memory controller 200 may identify a read operation and a page hit as a one-time access even when operation times of the read operation and the page hit are different from each other. In the case of the page hit, a read operation is performed a few times on the specific memory bank, and therefore, a probability that an interference phenomenon will occur may be higher than that of the general read operation.

In accordance with the embodiment of the disclosed technology, in the case of the idle state and the page hit, which are shown in FIGS. 7 and 8, an increment of a number of access times or a correction value is determined based on a time interval between active commands, so that an interference phenomenon or a charge leakage phenomenon according to an increase in active interval or time interval of access to the specific memory bank can be minimized.

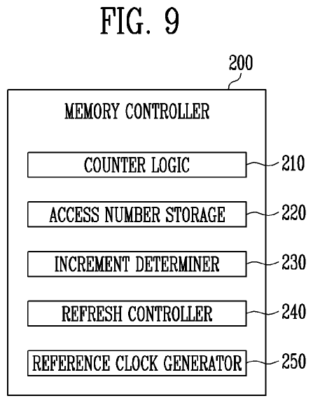

FIG. 9 is a diagram illustrating a configuration of a memory controller in accordance with an embodiment of the disclosed technology.

Referring to FIG. 9, the memory controller 200 may include a counter logic 210, an access number storage 220, an increment determiner 230, a refresh controller 240, and a reference clock generator 250.

The counter logic 210 may be a component for counting a number of access times to a plurality of banks included in the memory device 100. Specifically, the counter logic 210 may count a number of access times to each of the plurality of banks. For example, when the memory controller 200 receives a read request from the host 2000, the memory controller 200 may convert a logical address of the read request into a physical address, and the counter logic 210 may count a number of access times to a memory bank corresponding to the physical address. The counter logic 210 may count a number of access times to a specific memory bank, and information on the number of times of access, which is counted by the counter logic 210, may be stored for each memory bank in the access number storage 220.

The access number storage 220 may store the number of times of access to each of the plurality of memory banks included in the memory device 100. The access number storage 220 may store count information on the number of times of access to the memory bank, which is counted by the counter logic 210. When a refresh operation is performed on the specific memory bank, the access number storage 220 may initialize the number of times of access to the specific memory bank.

The increment determiner 230 may correct a number of access times based on a time interval between active commands. Specifically, the increment determiner 230 may determine an increment of the number of times of access for correcting the number of times of access or a correction value according to a time interval between a first active command and a second active command. The increment determiner 230 may determine the increment of the number of times of access such that the increment of the number of times of access increases as the time interval increases.

The refresh controller 240 may control the memory device 100 to perform the refresh operation. The refresh controller 240 may generate and transmit a refresh control signal or a refresh control command to the memory device 100 such that the memory device 100 performs the refresh operation on a target bank as a target of the refresh operation.

The reference clock generator 250 may generate a reference clock in a constant period. The memory controller 200 may calculate a time interval between active commands by using the reference clock generated by the reference clock generator 250. Specifically, after the memory controller 200 receives the first active command, the memory controller 200 may calculate a time interval, based on a number of reference clocks generated until the memory controller 200 receives the second active command. Meanwhile, the memory controller 200 may calculate a reference time of access by using the number of reference clocks generated by the reference clock generator 250. When the time interval between the active commands is n times of the reference time tRC of access, the increment of the number of times of access may be determined as (n−1).

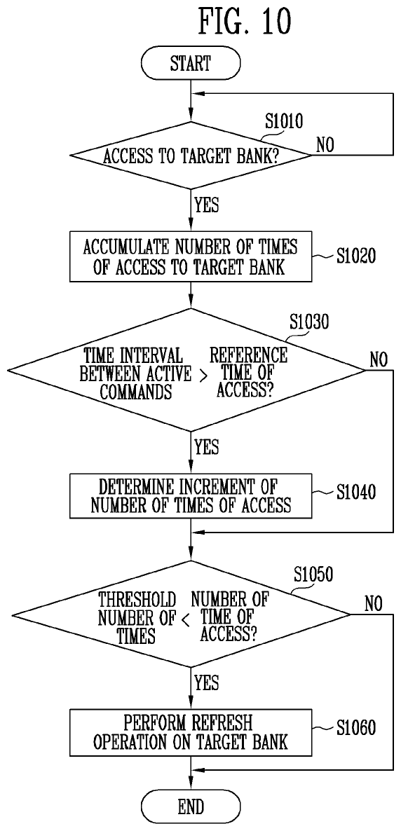

FIG. 10 is a diagram illustrating an operating method of the storage device in accordance with an embodiment of the disclosed technology.

Referring to FIG. 10, the storage device 1000 may receive a request for an internal operation from the host 2000. The storage device 1000 may generate an active command in response to the received request. The active command may be a command for performing the internal operation by accessing any one of a plurality of memory banks.

Also, the storage device 1000 may access a target bank among the plurality of memory banks, based on a physical address corresponding to the active command (S1010), and accumulate a number of access times to the target bank (S1020).

The storage device 1000 may compare a time interval between active commands with a referent time of access. Also, the storage device 1000 may determine a correction value of the number of times of access according to an input period of an active command for the target bank. Specifically, when the time interval between the active commands is greater than the reference time of access (S1030), the storage device 1000 may determine an increment of the number of times of access, based on the time interval between the active commands. Specifically, the storage device 1000 may determine an increment (or correction value) of the number of times of access such that the increment (or correction value) increases as the time interval between the active commands increases (S1040).

Also, the storage device 1000 may determine whether the number of times of access to the target bank exceeds a predetermined threshold number of times (S1050). When the number of times of access to the target bank exceeds the predetermined threshold number of times (S1050, YES), the storage device 1000 may perform a refresh operation on the target bank (S1060).

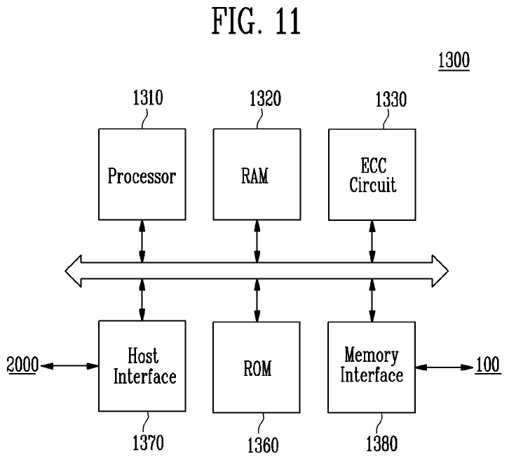

FIG. 11 is a block diagram illustrating a memory controller in accordance with another embodiment of the disclosed technology.

Referring to FIG. 11, the memory controller 1300 may include a processor 1310, a RAM 1320, and an ECC circuit 1330, a ROM 1360, a host interface 1370, and a memory interface 1380. The memory controller 1300 shown in FIG. 11 may be an embodiment of the memory controller 200 shown in FIG. 1.

The processor 1310 may communicate with the host 2000 by using the host interface 1370, and perform a logical operation to control an operation of the memory controller 1300. For example, the processor 1310 may load a program command, a data file, a data structure, etc., based on a request received from the host 2000 or an external device, and perform various operations or generate a command and an address. For example, the processor 1310 may generate various commands necessary for a program operation, a read operation, an erase operation, a suspend operation, and a parameter setting operation.

The RAM 1320 may be used as a buffer memory, a working memory, or a cache memory of the processor 1310. Also, the RAM 1320 may store codes and commands, which the processor 1310 executes. The RAM 1320 may store data processed by the processor 1310. Also, the RAM 1320 may be implemented, including a Static RAM (SRAM) or a Dynamic RAM (DRAM).

The ECC circuit 1330 may detect an error in a program operation or a read operation, and correct the detected error. Specifically, the ECC circuit 1330 may perform an error correction operation according to an Error Correction Code (ECC). Also, the ECC circuit 1330 may perform ECC encoding, based on data to be written to the memory device 100. The data on which the ECC encoding is performed may be transferred to the memory device 100 through the memory interface 1380. Also, the ECC circuit 1330 may perform ECC decoding on data received from the memory device 100 through the memory interface 1380.

The ROM 1360 may be used as a storage unit for storing various information necessary for an operation of the memory controller 1300. Specifically, the ROM 1360 may include a map table, and physical-to-logical address information and logical-to-physical address information may be stored in the map table. Also, the ROM 1360 may be controlled by the processor 1310.

The host interface 1370 may include a protocol for exchanging data between the host 2000 and the memory controller 1300. Specifically, the host interface 1370 may communicate with the host 2000 through at least one of various interface protocols such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer System Interface (SCSI) protocol, an Enhanced Small Disk Interface (ESDI) protocol, an Integrated Drive Electronics (IDE) protocol, and a private protocol.

The memory interface 1380 may communicate with the memory device 100 by using a communication protocol under the control of the processor 1310. Specifically, the memory interface 1380 may communicate a command, an address, and data with the memory device 100 through a channel.

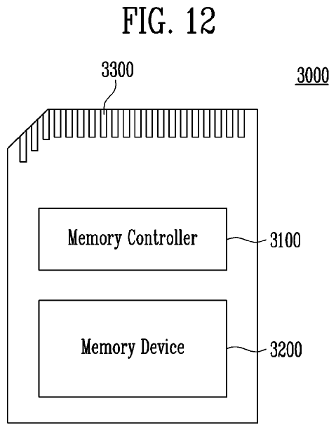

FIG. 12 is a diagram illustrating a memory card system in accordance with an embodiment of the disclosed technology.

Referring to FIG. 12, the memory card system 3000 includes a memory controller 3100, a memory device 3200, and a connector 3300.

The memory controller 3100 may be connected to the memory device 3200. The memory controller 3100 may access the memory device 3200. For example, the memory controller 3100 may control read, write, erase, and background operations on the memory device 3200. The memory controller 3100 may provide an interface between the memory device 3200 and a host. Also, the memory controller 3100 may drive firmware for controlling the memory device 3200.

For example, the memory controller 3100 may include components such as a Random Access Memory (RAM), a processing unit, a host interface, a memory interface, and the error corrector 233.

The memory controller 3100 may communicate with an external device through the connector 3300. The memory controller 3100 may communicate with the external device (e.g., the host) according to a specific communication protocol. For example, the memory controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, or NVMe. The memory controller 3100 and the memory device 3200 may be integrated into a single semiconductor device, to constitute a memory card.

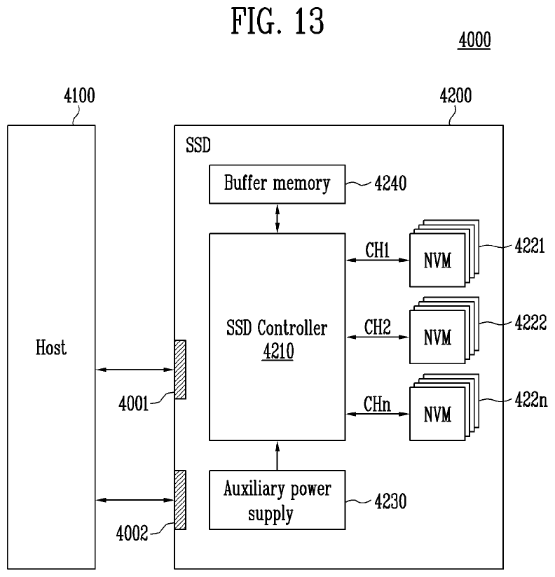

FIG. 13 is a diagram illustrating a Solid State Drive (SSD) in accordance with an embodiment of the disclosed technology.

Referring to FIG. 13, the SSD system 4000 includes a host 4100 and an SSD 4200. The SSD 4200 exchanges a signal SIG with the host 4100 through a signal connector 4001, and receives power PWR through a power connector 4002. The SSD 4200 includes an SSD controller 4210, a plurality of flash memories 4221 to 422n, an auxiliary power supply 4230, and a buffer memory 4240.

In an embodiment, the SSD controller 4210 may serve as the memory controller 200 described with reference to FIG. 1. The SSD controller 4210 may control the plurality of flash memories 4221 to 422n in response to a signal SIG received from the host 4100. For example, the signal SIG may be a signal based on an interface between the host 4100 and the SSD 4200. For example, the signal SIG may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, or an NVMe.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power of the SSD 4200. For example, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may temporarily store data received from the host 4100 or data received from the plurality of flash memories 4221 to 422n, or temporarily store meta data (e.g., a mapping table) of the flash memories 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

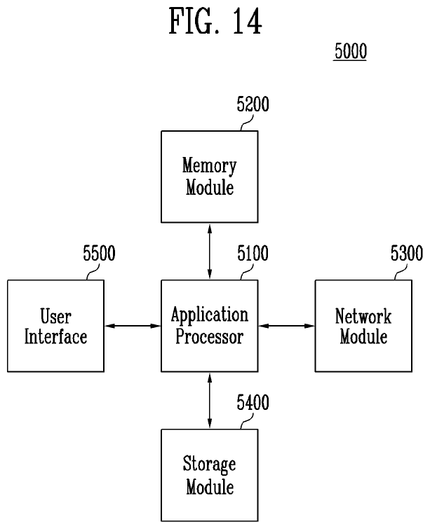

FIG. 14 is a diagram illustrating a user system in accordance with an embodiment of the disclosed technology.

Referring to FIG. 14, the user system 5000 includes an application processor 5100, a memory module 5200, a network module 5300, a storage module 5400, and a user interface 5500.

The application processor 5100 may drive components included in the user system 5000, an operating system (OS), a user program, or the like. For example, the application processor 5100 may include controllers for controlling components included in the user system 5000, interfaces, a graphic engine, and the like. The application processor 5100 may be provided as a System-on-Chip (SoC).

The memory module 5200 may operate as a main memory, working memory, buffer memory or cache memory of the user system 5000. The memory module 5200 may include volatile random access memories such as a DRAM, an SDRAM, a DDR SDRAM, a DDR2 SDRM, a DDR3 SDRAM, an LPDDR SDRAM, an LPDDR2 SDRAM, and an LPDDR3 SDRAM or nonvolatile random access memories such as a PRAM, a ReRAM, an MRAM, and a FRAM. For example, the application processor 5100 and the memory module 5200 may be provided as one semiconductor package by being packaged based on a Package on Package (PoP).

In some implementations, the memory module 5200 may include a plurality of nonvolatile memory devices, and the plurality of nonvolatile memory devices may operate identically to the memory device described with reference to FIGS. 1 to 10. The memory module 5200 may operate identically to the storage device 1000 described with reference to FIG. 1.

The network module 5300 may communicate with external devices. For example, the network module 5300 may support wireless communications such as Code Division Multiple Access (CDMA), Global System for Mobile communication (GSM), Wideband CDMA (WCDMA), CDMA-2000, Time Division Multiple Access (TDMA), Long Term Evolution (LTE), Wimax, WLAN, UWB, Bluetooth, and Wi-Fi. For example, the network module 5300 may be included in the application processor 5100.

The storage module 5400 may store data. For example, the storage module 5400 may store data received from the application processor 5100. Alternatively, the storage module 5400 may transmit data stored therein to the application processor 5100. For example, the storage module 5400 may be implemented with a nonvolatile semiconductor memory device such as a Phase-change RAM (PRAM), a Magnetic RAM (MRAM), a Resistive RAM (RRAM), a NAND flash, a NOR flash, or a NAND flash having a three-dimensional structure. For example, the storage module 5400 may be provided as a removable drive such as a memory card of the user system 5000 or an external drive.

The user interface 5500 may include interfaces for inputting data or commands to the application processor 5100 or outputting data to an external device. For example, the user interface 5500 may include user input interfaces such as a keyboard, a keypad, a button, a touch panel, a touch screen, a touch pad, a touch ball, a camera, a microphone, a gyroscope sensor, a vibration sensor, or a piezoelectric element. The user interface 4500 may include user output interfaces such as a Liquid Crystal Display (LCD), an Organic Light Emitting Diode (OLED) display device, an Active Matrix OLED (AMOLED) display device, an LED, a speaker, or a monitor.

In accordance with the disclosed technology, there can be provided a storage device for performing an improved refresh operation and an operating method of the storage device.

While the disclosed technology has been shown and described with reference to certain exemplary embodiments thereof, it will be understood by those skilled in the art that various changes in form and details may be made.

Various modifications and enhancements of the disclosed embodiments and other embodiments can be made based on what is disclosed in this patent document.

What is claimed is:

1. A storage device, comprising:
a memory device including memory cells for storing data, the memory cells grouped into a plurality of memory banks; and
a memory controller coupled in communication with the memory device and configured to provide commands to the memory device and access one or more memory banks based on address information associated with the commands,
wherein the memory controller is further configured to:
count a number of access times that the memory controller has accessed to first memory bank by increasing the number of access times to the first memory bank based on a time interval between first active command and second active command for the first memory bank; and
transmit, to the memory device, a control signal to perform a refresh operation on the first memory bank when the number of access times counted exceeds a predetermined number.

2. The storage device of claim 1, wherein the memory controller further includes an increment determiner configured to determine the amount of the increase in the number of access times based on the time interval.

3. The storage device of claim 2, wherein the increment determiner is configured to determine the amount of the increase in the number of access times such that the increment of the number of access times increases as the time interval increases.

4. The storage device of claim 1, wherein the memory controller further includes a refresh controller configured to control the memory device to perform the refresh operation on the first memory bank.

5. The storage device of claim 1, wherein the memory controller further includes an access number storage configured to store the number of access times counted for each of the plurality of memory banks.

6. The storage device of claim 1, wherein the memory controller is further configured to initialize the number of access times to the first memory bank in response to the refresh operation performed on the first memory bank.

7. The storage device of claim 1, wherein the memory controller further includes a counter logic configured to count the number of access to each of the plurality of memory banks.

8. The storage device of claim 1, wherein the memory controller further includes a reference clock generator configured to generate a reference clock at a constant period, and
wherein the memory controller is further configured to calculate the time interval based on a number of reference clocks generated between the first active command and the second active command.

9. The storage device of claim 8, wherein the memory controller is further configured to increase the number of access times by (n−1) in case that the time interval is n times of a reference access time that is predefined as a predetermined number of reference clocks.

10. A storage device, comprising:
a memory device including a plurality of memory banks; and
a memory controller in communication with the memory device and configured to:
transmit, to the memory device, a first command and a second command subsequent to the first command that are associated with a memory bank;
identify the memory bank to which the memory controller accesses based on the first command and the second command;
count a number of access times that the memory controller has accessed to the memory bank based on a time interval between the first command and the second command; and
transmit a control signal, to the memory device, to perform a refresh operation on the memory block in case that the number of access times to the memory bank exceeds a predetermined threshold number.

11. The storage device of claim 10, wherein the memory controller further includes an increment determiner configured to determine an amount of an increase in the number of access times based on the time interval.

12. The storage device of claim 11, wherein the amount of the increase is in proportional to the time interval.

13. The storage device of claim 10, wherein the memory controller further includes a refresh controller configured to control the memory device to perform the refresh operation on the memory bank.

14. The storage device of claim 10, wherein the memory controller further includes an access number storage configured to store the number of access times counted for the memory bank.

15. The storage device of claim 10, wherein the memory controller is further configured to initialize the number of access times to the memory bank in response to the refresh operation.

16. The storage device of claim 10, wherein the memory controller further includes a counter logic configured to count the number of access times to the memory bank.

17. The storage device of claim 10, wherein the memory controller further includes a reference clock generator configured to generate a reference clock at a constant period, and
wherein the memory controller is further configured to calculate the time interval based on a number of reference clocks generated between the first command and the second command.

18. The storage device of claim 17, wherein the memory controller is further configured to count the number of times of access by increasing as (n−1) in case that the time interval is n times of a reference time of access that is predefined as a predetermined number of reference clocks.

19. A method for operating a storage device, the method comprising:
generating a first command and a second command for controlling a memory device including memory banks to perform corresponding operations on a memory bank, each memory bank including memory cells for storing data;
counting a number of access times to the memory bank based on a time interval between of the first command and the second command;
transmitting a control signal to perform a refresh operation on the memory bank in case that the number of access times to the memory bank exceeds a threshold number.

20. The method of claim 19, wherein the counting of the number of access times is performed such that an amount of an increase in the number of access times is in proportional to the time interval.
